(19) United States
(12) Patent Application Publication
(10) Pub. No.: US 2026/0143842 A1
(43) Pub. Date: May 21, 2026

(54) IMAGE SENSOR

(71) Applicant: Samsung Electronics Co., Ltd., Suwon-si (KR)

(72) Inventors: Jin Suk HUH, Suwon-si (KR); Seon Ok KIM, Suwon-si (KR); Hyung Chae KIM, Suwon-si (KR)

(21) Appl. No.: 19/394,952

(22) Filed: Nov. 20, 2025

(30) Foreign Application Priority Data
Nov. 21, 2024 (KR) 10-2024-0167799

(51) Int. Cl. H10F 39/00

(52) U.S. Cl. CPC H10F 39/807; H10F 39/8037; H10F 39/8053; H10F 39/8063; H10F 39/811

(57) ABSTRACT

An image sensor includes a substrate and an outer separation structure separating the substrate into color unit regions, each including a plurality of sub-regions and a floating diffusion region, and for each color unit region, the plurality of sub-regions include a first sub-region and a second sub-region, which share the floating diffusion region. Each sub-region includes: a first doped region arranged adjacent to a first surface of the substrate and doped with impurities having a first conductivity type, a second doped region spaced apart from the first surface and doped with impurities having a second conductivity type, the first doped region being arranged between the first surface and the second doped region, and a third doped region spaced apart from the first surface and doped with impurities having the first conductivity type. A doping concentration of the second doped region is different from that of the second doped region.

### CROSS-REFERENCE TO RELATED APPLICATION

This application claims priority from Korean Patent Application No. 10-2024-0167799, filed on Nov. 21, 2024 in the Korean Intellectual Property Office and all the benefits accruing therefrom under 35 U.S.C. 119, the contents of which in its entirety are herein incorporated by reference.

### BACKGROUND

### Technical Field

The present disclosure relates to an image sensor.

### Description of the Related Art

Image sensors that receive images and convert them into electrical signals have been used in various fields such as digital cameras, camcorders, personal communication systems (PCS), game devices, security cameras, and medical micro cameras. With the high integration of the image sensor and the miniaturization of a pixel size, a shared pixel structure has been employed in these image sensors. Recently, it has become more desirable for image sensors to have a structure that can be obtained through a simplified process while making sure to maintain stable electrical characteristics required in the shared pixel structure.

### BRIEF SUMMARY

An object of the present disclosure is to provide an image sensor with improved performance.

The objects of the present disclosure are not limited to those mentioned above and additional objects of the present disclosure, which are not mentioned herein, will be clearly understood by those skilled in the art from the following description of the present disclosure.

According to an aspect of the present disclosure, an image sensor includes a substrate and an outer separation structure separating the substrate into a plurality of color unit regions. Each of the color unit regions includes a plurality of sub-regions and a floating diffusion region, and for each color unit region, the plurality of sub-regions include a first sub-region and a second sub-region, which share the floating diffusion region. Each of the sub-regions includes: a first doped region arranged adjacent to a first surface of the substrate and doped with impurities having a first conductivity type, a second doped region spaced apart from the first surface and doped with impurities having a second conductivity type different from the first conductivity type, the first doped region being arranged between the first surface and the second doped region, and a third doped region spaced apart from the first surface and doped with impurities having the first conductivity type. A doping concentration of the second doped region of the first sub-region is different from a doping concentration of the second doped region of the second sub-region.

According to the aforementioned and other embodiments of the present disclosure, an image sensor includes a substrate, an outer separation structure separating the substrate into a plurality of color unit regions, and an inner separation structure separating each of the color unit regions into first to fourth sub-regions and passing through at least a portion of the substrate. Each of the color unit regions includes a floating diffusion region. For each color unit region, the first to fourth sub regions share a floating diffusion region and each include: a first doped region arranged adjacent to a first surface of the substrate and doped with impurities having a first conductivity type, a second doped region spaced apart from the first surface and doped with impurities having a second conductivity type different from the first conductivity type, the first doped region being arranged between the first surface and the second doped region, and a third doped region spaced apart from the first surface and doped with impurities having the first conductivity type. A doping concentration of the second doped region of the first sub-region is less than a doping concentration of the second doped region of the second sub-region.

According to the aforementioned and other embodiments of the present disclosure, an image sensor includes a substrate, an outer separation structure separating the substrate into a plurality of color unit regions, an inner separation structure separating each color unit region of the color unit regions into first to fourth sub-regions and passing through at least a portion of the substrate, a wiring layer formed on a first surface of the substrate, including wirings electrically connected to the substrate, a color filter formed on a second surface opposite to the first surface of the substrate, and a microlens formed on the color filter. For each color unit region: the color unit region includes a floating diffusion region, the first to fourth sub-regions share the floating diffusion region and each includes: a first doped region electrically connected to a pixel power source through the wiring and doped with impurities having a first conductivity type, a second doped region spaced apart from the first surface and doped with impurities having a second conductivity type different from the first conductivity type, the first doped region being arranged between the first surface and the second doped region, a third doped region doped with impurities having the first conductivity type, the third doped region generating electric charges by reacting with light, and a transmission transistor providing the electric charges in the third doped region to the floating diffusion region. A doping concentration of the second doped region of the first sub-region is less than a doping concentration of the second doped region of the second sub-region.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram illustrating an image sensing device according to some embodiments.

FIG. 2 is an exemplary circuit view illustrating a pixel unit included in an image sensor according to embodiments of the present disclosure.

FIG. 3 is a schematic plan view illustrating an image sensor according to embodiments of the present disclosure.

FIG. 4 is a schematic plan view illustrating some components of the image sensor shown in FIG. 3.

FIG. 5 is a cross-sectional view taken along line A-A′ of FIG. 4.

FIGS. 6 and 7 are cross-sectional views taken along line B-B′ of FIG. 4.

FIG. 8 is a potential view illustrating an image sensor according to some embodiments.

FIG. 9 is a cross-sectional view illustrating an effect of an image sensor according to some embodiments.

FIG. 10 is a schematic plan view illustrating some components of an image sensor according to some embodiments.

FIG. 11 is a cross-sectional view taken along line C-C′ of FIG. 10.

FIG. 12 is a cross-sectional view taken along line D-D′ of FIG. 10.

FIG. 13 is an exemplary circuit view illustrating a pixel unit included in an image sensor according to embodiments of the present disclosure.

FIG. 14 is a schematic plan view illustrating some components of an image sensor according to some embodiments.

FIG. 15 is a cross-sectional view illustrating effects of an image sensor according to some embodiments.

### DETAILED DESCRIPTION OF THE DISCLOSURE

Hereinafter, embodiments of the present disclosure will be described in detail with reference to the accompanying drawings. The same reference numerals will be used for the same components in the drawings, and their redundant description will be omitted.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim

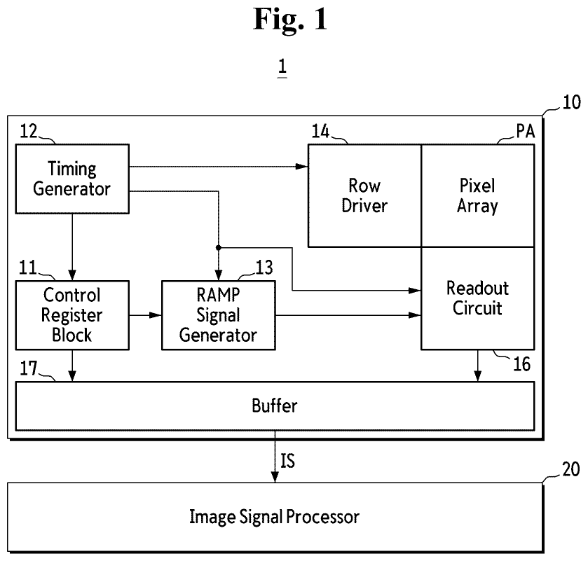

FIG. 1 is a block diagram illustrating an image sensing device according to some embodiments.

Referring to FIG. 1, an image sensing device 1 according to some embodiments may include an image sensor 10 and an image signal processor 20.

The image sensor 10 may generate an image signal IS by sensing an image of a sensing target by using light. In some embodiments, the generated image signal IS may be, for example, a digital signal, but embodiments according to the technical spirit of the present disclosure are not limited thereto.

The image signal IS may be processed by being provided to the image signal processor 20. The image signal processor 20 may receive the image signal IS output from a buffer 17 of the image sensor 10 and process the received image signal IS to facilitate display of the processed image signal IS.

In some embodiments, the image signal processor 20 may perform digital binning for the image signal IS output from the image sensor 10. In this case, the image signal IS output from the image sensor 10 may be a raw image signal from a pixel array PA without analog binning, or may be an image signal IS for which analog binning has been already performed.

In some embodiments, the image sensor 10 and the image signal processor 20 may be separated from each other as shown. For example, the image sensor 10 may be mounted or formed on a first chip, and the image signal processor 20 may be mounted or formed on a second chip, so that the image sensor 10 and the image signal processor 20 may perform communication with each other through a predetermined interface, but the embodiments are not limited thereto. The image sensor 10 and the image signal processor 20 may be implemented as one package, for example, a multi-chip package (MCP).

The image sensor 10 may include a pixel array PA, a control register block 11, a timing generator 12, a row driver 14, a readout circuit 16, a ramp signal generator 13, and a buffer 17.

The control register block 11 may control the overall operation of the image sensor 10. In particular, the control register block 11 may directly transmit an operation signal to the timing generator 12, the ramp signal generator 13 and the buffer 17.

The timing generator 12 may generate a signal that is a reference of an operation timing of various components of the image sensor 10. The operation timing reference signal generated by the timing generator 12 may be transferred to the ramp signal generator 13, the row driver 14, the readout circuit 16 and the like.

The ramp signal generator 13 may generate and transmit a ramp signal used in the readout circuit 16. For example, the readout circuit 16 may include a correlated double sampler CDS, a comparator and the like, and the ramp signal generator 13 may generate and transmit a ramp signal used for the correlated double sampler CDS, the comparator and the like.

The row driver 14 may selectively activate rows of the pixel array PA.

The pixel array PA may sense an external image. The pixel array PA may include a plurality of pixels arranged two-dimensionally (e.g., in the form of matrix).

The readout circuit 16 may sample a pixel signal received from the pixel array PA, compare the sampled pixel signal with the ramp signal and then convert an analog image signal (data) into a digital image signal (data) based on the compared result.

The buffer 17 may include, for example, a latch unit. The buffer 17 may temporarily store the image signal IS to be provided to the outside, and may transmit the image signal IS to an external memory or an external device.

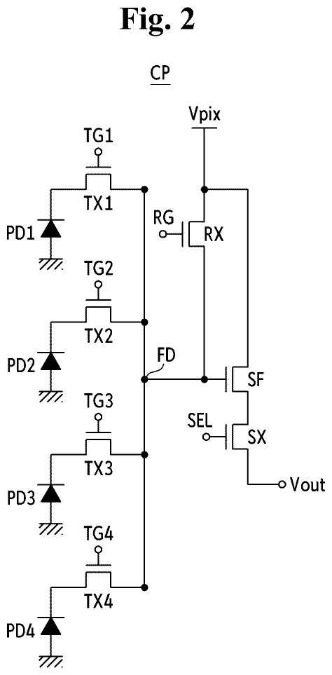

FIG. 2 is an exemplary circuit view illustrating a pixel unit included in an image sensor according to embodiments of the present disclosure.

Referring to FIG. 2, a pixel array 10 includes a plurality of color unit pixels CP, and the color unit pixels CP may be arranged along rows and columns. Each color unit pixel CP may include four photodiodes PD1, PD2, PD3 and PD4 and four transmission transistors TX1, TX2, TX3 and TX4. The four transmission transistors TX1, TX2, TX3 and TX4 may share a floating diffusion region FD and read circuits RX, SF and SX. The read circuit may include a reset transistor RX, a selection transistor SX, and a source follower transistor SF. In some embodiments, although it is illustrated that each color unit pixel CP includes four photoelectric conversion elements and four transmission transistors, the present disclosure is not limited thereto, and each color unit pixel CP may include two photodiodes and two transmission transistors. The first to fourth photodiodes PD1, PD2, PD3 and PD4 may generate and accumulate photocharges in proportion to the amount of light incident from the outside.

The first to fourth transmission transistors TX1, TX2, TX3 and TX4 transmit electric charges accumulated in the first to fourth photodiodes PD1, PD2, PD3 and PD4 to the floating diffusion region FD. The first to fourth transmission transistors TX1, TX2, TX3 and TX4 may be controlled by first to fourth gate signals TG1, TG2, TG3 and TG4, and the electric charges may be transmitted from any one of the first to fourth photodiodes PD1, PD2, PD3 and PD4 to the floating diffusion region FD in accordance with the first to fourth gate signals TG1, TG2, TG3 and TG4. The floating diffusion region FD receives the electric charges generated by the first to fourth photodiodes PD1, PD2, PD3 and PD4 and accumulatively stores the electric charges. The source follower transistor SF may be controlled depending on the amount of photocharges accumulated in the floating diffusion region FD.

The reset transistor RX may periodically reset the electric charges accumulated in the floating diffusion region FD. In detail, a source electrode of the reset transistor RX is connected to the floating diffusion region FD, and a drain electrode of the reset transistor RX is connected to a pixel voltage VPIX (e.g., a pixel voltage source). When the reset transistor RX is turned on, the pixel voltage VPIX connected to the drain electrode of the reset transistor RX is transferred to the floating diffusion region FD. Therefore, when the reset transistor RX is turned on, the electric charges accumulated in the floating diffusion region FD may be discharged to reset the floating diffusion region FD.

The source follower transistor SF may be a source follower buffer amplifier that generates a source-drain current in proportion to the amount of photocharges input to a gate electrode. The source follower transistor SF amplifies a potential change in the floating diffusion region FD and outputs a signal amplified through the selection transistor SX to an output line VOUT. A source electrode of the source follower transistor SF may be connected to the pixel voltage VPIX, and a drain of the source follower transistor SF may be connected to a source of the selection transistor SX.

The selection transistor SX may select a color unit pixel CP to be read in units of rows. When the selection transistor SX is turned on, an electrical signal output to the drain electrode of the source follower transistor SF may be output to the output line VOUT.

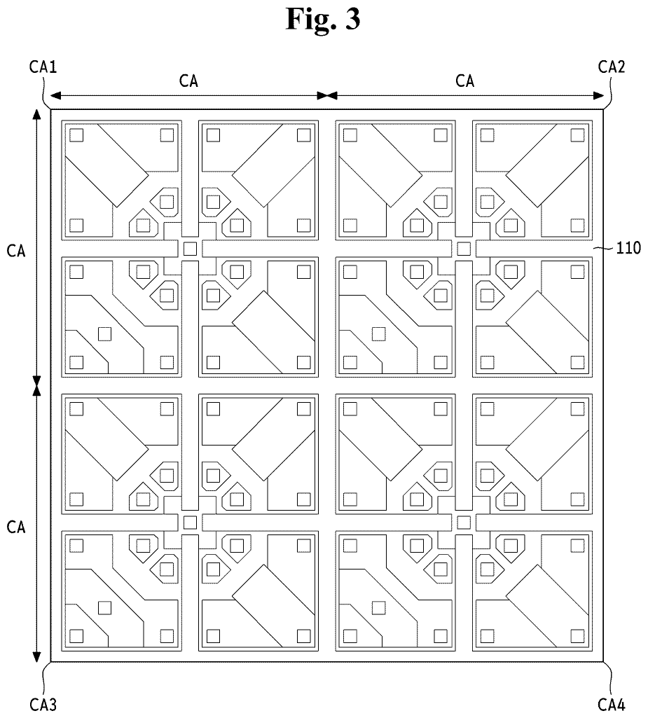

FIG. 3 is a schematic plan view illustrating an image sensor according to embodiments of the present disclosure.

Referring to FIG. 3, when viewed in a plan view, a plurality of color unit regions CA1, CA2, CA3 and CA4 may be arranged in a matrix form along x-axis and y-axis directions. Each of the plurality of color unit regions CA1, CA2, CA3 and CA4 may be defined by an outer separation structure 110. The outer separation structure 110 may be formed by ion-implanting impurities of a first conductivity type (e.g., p-type impurities) into a substrate 100. The concentration of p-type impurities in the outer separation structure 110 may be greater than the concentration of p-type impurities in the substrate 100. A region or structure doped with impurities of a particular conductivity type may be described as being doped with that particular conductivity type. Also, a region or structure doped with impurities maybe described herein as a doped region.

Each of the plurality of color unit regions CA1, CA2, CA3 and CA4 may include components of a color unit pixel CP shown in FIG. 2. For example, each color unit region may be a unit pixel having a single color.

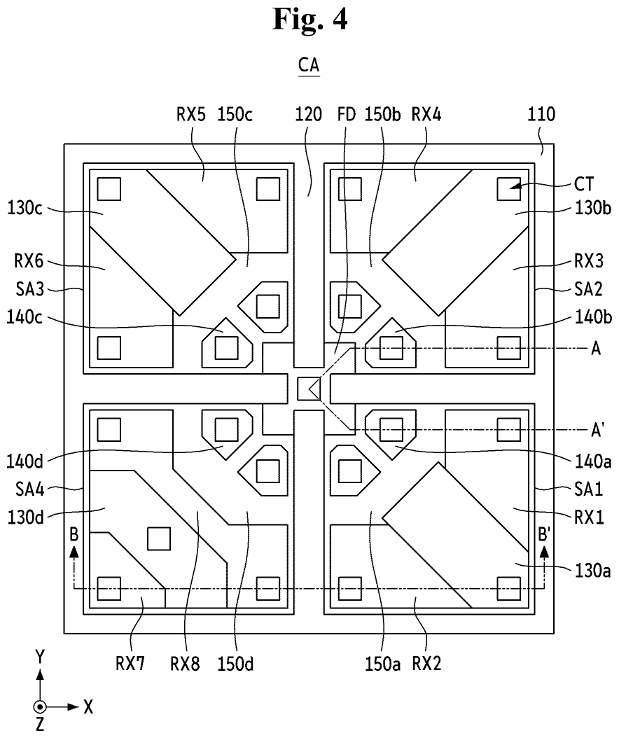

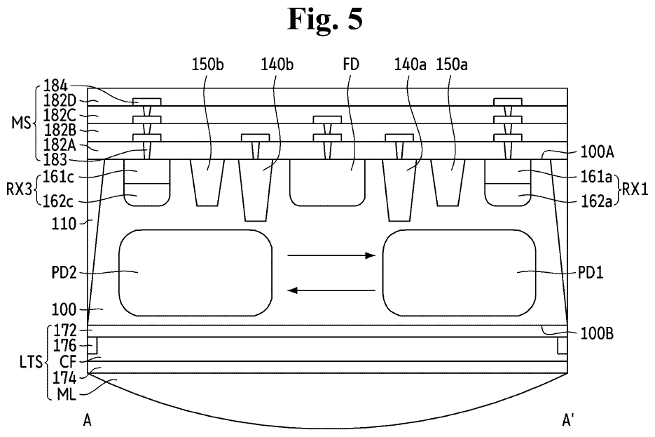

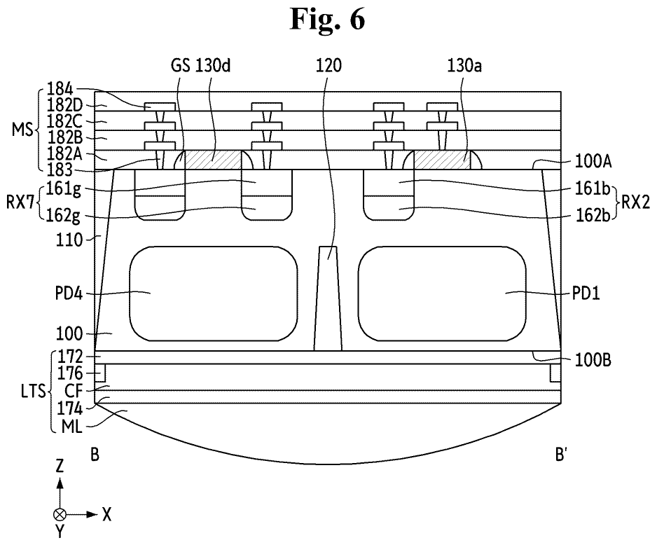

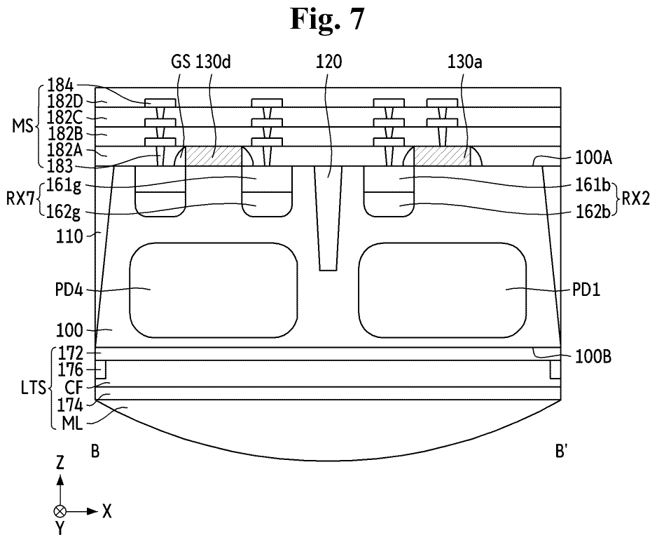

FIG. 4 is a schematic plan view illustrating some components of the image sensor shown in FIG. 3. FIG. 5 is a cross-sectional view taken along line A-A′ of FIG. 4. FIGS. 6 and 7 are cross-sectional views taken along line B-B′ of FIG. 4. A color unit region CA of FIG. 4 may be the same as any one of the plurality of color unit regions CA1, CA2, CA3 and CA4 of FIG. 3.

Referring to FIGS. 4 to 7, the color unit region CA may include a floating diffusion region FD and a plurality of sub-regions SA1, SA2, SA3 and SA4 that share the floating diffusion region FD. Areas of the sub-regions SA1, SA2, SA3 and SA4 may be substantially the same as one another. The first to fourth sub-regions SA1 to SA4 may be arranged outside in a radial direction based on the floating diffusion region FD so as to surround the floating diffusion region FD. The floating diffusion region FD may be formed by ion-implanting impurities of a second conductivity type (e.g., n-type) into the substrate 100.

An inner separation structure 120 protruding from the outer separation structure 110 may be formed between sub-regions of the plurality of sub-regions SA1, SA2, SA3 and SA4. Accordingly, the inner separation structure 120 may prevent electric crosstalk and optical crosstalk from occurring between the first to fourth photodiodes PD1, PD2, PD3 and PD4 included in the plurality of sub-regions SA1, SA2, SA3 and SA4, thereby contributing to improvement of auto-focusing characteristics in the color unit pixel CP.

The first to fourth sub-regions SA1 to SA4 may include photodiodes PD1, PD2, PD3 and PD4, transfer gate electrodes 140a, 140b, 140c and 140d, gate electrodes 130a, 130b, 130c and 130d, active regions RX1 to RX8, and device isolation patterns 150a, 150b, 150c and 150d, respectively.

The photodiodes PD1, PD2, PD3 and PD4 may be provided in the substrate 100 in each of the first to fourth sub-regions SA1 to SA4. The photodiodes PD1, PD2, PD3 and PD4 may generate photocharges in proportion to the intensity of incident light. The photodiodes PD1, PD2, PD3 and PD4 may be formed by ion-implanting impurities of the second conductivity type opposite to the first conductivity type of the substrate 100 into the substrate 100. For example, the substrate 100 of the first conductivity type may be a silicon epitaxial layer doped with p-type impurities. Photodiodes may be doped regions formed by junction between the substrate 100 of the first conductivity type and the photodiodes PD1, PD2, PD3 and PD4 of the second conductivity type.

The transfer gate electrodes 140a, 140b, 140c and 140d may be provided in the substrate 100 in each of the first to fourth sub-regions SA1 to SA4. The electric charges may be transmitted from one of the first to fourth photodiodes PD1, PD2, PD3 and PD4 to the floating diffusion region FD in accordance with the first to fourth gate signals TG1, TG2, TG3 and TG4. The first to fourth photodiodes PD1, PD2, PD3 and PD4 may constitute source regions of the first to fourth transmission transistors TX1, TX2, TX3 and TX4, respectively. Also, the first transmission transistor TX1 corresponding to the first photodiode PD1, the second transmission transistor TX2 corresponding to the second photodiode PD2, the third transmission transistor TX3 corresponding to the third photodiode PD3 and the fourth transmission transistor TX4 corresponding to the fourth photodiode PD4 may share one floating diffusion region FD as a common drain region.

When viewed in a plan view, the transfer gate electrodes 140a, 140b, 140c and 140d may partially overlap the photodiodes PD1, PD2, PD3 and PD4. The transfer gate electrodes 140a, 140b, 140c and 140d may vertically pass through a portion of the substrate 100. Bottom surfaces of the transfer gate electrodes 140a, 140b, 140c and 140d may be positioned at a lower level than a first surface 100A of the substrate 100. Although the transmission transistor is illustrated in a form having a vertical transfer gate, the embodiments of the present disclosure are not limited thereto. For example, the transmission transistor may correspond to a planar structure.

The gate electrodes 130a, 130b, 130c and 130d may be arranged on the first surface 100A of the substrate 100. A gate spacer GS may be formed on sides of the gate electrodes 130a, 130b, 130c and 130d. The gate spacer GS may include, for example, silicon nitride, silicon carbonitride, or silicon oxynitride.

The active regions RX1 to RX8 may be defined by the device isolation patterns 150a, 150b, 150c and 150d arranged in the substrate 100. The device isolation patterns 150a, 150b, 150c and 150d may extend from the first surface 100A of the substrate 100 into the substrate 100. The device isolation patterns 150a, 150b, 150c and 150d may extend from the first surface 100A of the substrate 100 toward a second surface 100B of the substrate 100. For example, the device isolation patterns 150a, 150b, 150c and 150d may be formed by filling an insulating material in a shallow trench formed by patterning the substrate 100 including the first surface 100A. For example, the device isolation patterns 150a, 150b, 150c and 150d may include or consist of at least one of silicon oxide, silicon nitride, silicon oxynitride, or their combination.

The read circuits RX, SF, and SX included in the color unit pixel CP may be formed by the active regions RX1 to RX8 and the gate electrodes 130a, 130b, 130c and 130d, which are included in the first to fourth sub-regions SA1 to SA4. In addition, the first to fourth photodiodes PD1, PD2, PD3 and PD4 may share the reset transistor RX, the source follower transistor SF and the selection transistor SX.

The active regions RX1 to RX8 may include sources/drain regions 161a to 161h and potential barrier regions 162a to 162h. The source/drain regions 161a to 161h may be a doped region formed by doping a region adjacent to the first surface 100A of the substrate 100 with impurities of a second conductivity type (e.g., n-type impurities). The source/drain regions 161a to 161h may constitute a source region or a drain region, which is included in the read circuits RX, SF and SX. The potential barrier regions 162a to 162h are spaced apart from the first surface 100A, and may be doped regions formed by doping impurities of a first conductivity type (e.g., p-type impurities) into the substrate 100 between the first surface 100A of the substrate 100 and the potential barrier regions 162a to 162h. The potential barrier regions 162a to 162h may provide a potential barrier between the photodiodes PD1, PD2, PD3 and PD4 and the source/drain regions 161a to 161h.

For example, referring to FIG. 5, the first active region RX1 may include a first source/drain region 161a and a first potential barrier region 162a. The third active region RX3 may include a third source/drain region 161c and a third potential barrier region 162c. The first potential barrier region 162a may provide a potential barrier between the first photodiode PD1 and the first source/drain region 161a. The third potential barrier region 162c may provide a potential barrier between the second photodiode PD2 and the third source/drain region 161c.

Referring back to FIGS. 4 to 7, a wiring structure MS may be arranged on the first surface 100A of the substrate 100. The wiring structure MS may include interlayer insulating films 182A, 182B, 182C and 182D of a multilayer structure covering the first to fourth transmission transistors TX1, TX2, TX3 and TX4, a via 183 formed on each of the interlayer insulating films 182A, 182B, 182C and 182D, and a plurality of wiring layers 184 of a multilayer structure. The number and arrangement of layers of each of the interlayer insulating films 182A, 182B, 182C and 182D and the plurality of wiring layers 184 are not limited to the shown example, and may be variously changed and modified as necessary.

The plurality of wiring layers 184 included in the wiring structure MS may be included in a plurality of transistors electrically connected to the first to fourth photodiodes PD1, PD2, PD3 and PD4, and may comprise wirings connected to the plurality of transistors. The plurality of transistors may include the first to fourth transmission transistors TX1, TX2, TX3 and TX4, a reset transistor RX, a source follower SF, and a selection transistor SX, which are illustrated in FIG. 2. The electrical signals converted by the first to fourth photodiodes PD1, PD2, PD3 and PD4 may be signal-processed in the wiring structure MS. The arrangement of the plurality of wiring layers 184 may be freely arranged regardless of the arrangement of the first to fourth photodiodes PD1, PD2, PD3 and PD4.

A light-transmissive structure LTS may be arranged on the second surface 100B of the substrate 100. The light-transmissive structure LTS may include a first planarization film 172, a color filter CF, a second planarization film 174, and a microlens ML, which are sequentially stacked on the second surface 100B. The light-transmissive structure LTS may condense and filter light incident from the outside. The first to fourth photodiodes PD1, PD2, PD3 and PD4 in one color unit region CA may be covered with one microlens ML. The color unit pixel CP may have a backside illumination (BSI) structure that receives light from the second surface 100B of the substrate 100.

In the light-transmissive structure LTS, the first planarization film 172 may be used as a buffer film for preventing the substrate 100 from being damaged during the manufacturing process of the image sensor 10. Each of the first planarization film 172 and the second planarization film 174 may be formed of a silicon oxide film, a silicon nitride film, a resin or their combination, but is not limited thereto.

In the embodiments, the color filter CF may be a red color filter, a green color filter, a blue color filter, or a white color filter. The white color filter may be a transparent color filter that transmits light of a visible wavelength band. The pixel array 10 illustrated in FIG. 1 may include a plurality of color filter groups in which a red color filter, a green color filter, a blue color filter and a white color filter are arranged in a 2×2 two-dimensional array to form one color filter group. The plurality of color filter groups may be arranged in a matrix form along a plurality of row lines and a plurality of column lines. In other embodiments, the color filter CF may have another color such as cyan, magenta or yellow.

The microlens ML may have an outwardly convex shape to condense light incident on the first to fourth photodiodes PD1, PD2, PD3 and PD4.

The light-transmissive structure LTS may further include an anti-reflective film 176 formed on the first planarization film 172. An upper surface and a sidewall of the anti-reflective film 176 may be covered with the color filter CF. The anti-reflective film 176 may serve to prevent incident light passing through the color filter CF from being reflected or scattered in a lateral direction. For example, the anti-reflective film 176 may prevent a photon reflected or scattered on an interface between the color filter CF and the first planarization film 172 from moving to another sensing region. The anti-reflective film 176 may include metal. For example, the anti-reflective film 126 may include tungsten (W), aluminum (Al), copper (Cu), or their combination.

Referring to FIGS. 4 and 5, there may be an overflow between the first photodiode PD1 and the second photodiode PD2, which are adjacent to each other. Accordingly, an electric charge amount exceeding a full well capacity (FWC) in either the first photodiode PD1 or the second photodiode PD2 may flow to the first to fourth photodiodes PD1 to PD4. However, in a high-illumination environment, the electric charges in the first photodiode PD1 or the second photodiode PD2, which exceed the full well capacity (FWC) of the first to fourth photodiode PD1 to PD4, may flow to the floating diffusion region FD. In this case, a reset level of the floating diffusion region FD may be reduced, whereby a sunspot defect may occur.

According to some embodiments of the present disclosure, a doping concentration of the first potential barrier region 162a may be different from a doping concentration of the third potential barrier region 162c. For example, the doping concentration of the first potential barrier region 162a may be lower than the doping concentration of the third potential barrier region 162c. A doping concentration of a region, or a concentration of impurities in a region, as described herein, may refer to a number of atoms of an impurity within a particular volume of a component. For example, a greater doping concentration may refer to a greater number of atoms per volume, while a smaller doping concentration may refer to a smaller number of atoms per the same volume. For example, first potential barrier region 162a may have the same structure, shape, and/or volume, as the third potential barrier region 162c, but may have a smaller amount of dopant material (e.g., fewer atoms of a dopant material). As the first potential barrier region 162a having a low doping concentration is provided, a potential barrier between the first photodiode PD1 and the first source/drain region 161a may be lowered. Therefore, the electric charges exceeding the full well capacity (FWC) in the first photodiode PD1 may overflow to the first source/drain region 161a. The first source/drain region 161a may be electrically connected to the pixel voltage VPIX through the wiring layer 184. The electric charges accumulated in the first source/drain region 161a may be discharged by the pixel voltage VPIX. Therefore, the first source/drain region 161a may function as a discharge path in the color unit region CA.

Also, an overflow of electric charges may occur between the first to fourth photodiodes PD1 to PD4. Therefore, the electric charges exceeding the full well capacity (FWC) of the first to fourth photodiodes PD1 to PD4 may flow to the first source/drain region 161a. For example, since the overflow of electric charges is possible between the plurality of photodiodes PD1, PD2, PD3 and PD4 in the color unit region CA, one photodiode (the first photodiode PD1 in FIG. 5) may function as the discharge path for the entire color unit region CA. As a result, since the discharge path is not required for each of the plurality of sub-regions SA1, SA2, SA3 and SA4, an image sensor in which process efficiency is increased and a sunspot defect is resolved may be provided. Although only one discharge path for the entire color unit region CA has been described in the present disclosure, this is exemplary, and the embodiments of the present disclosure are not limited thereto. There may be two or more discharge paths for the color unit region CA.

Referring to FIGS. 4 and 6, the inner separation structure 120 for separating the color unit region CA into the first to fourth sub regions SA1 to SA4 may be arranged in the substrate 100. The inner separation structure 120 may extend from the first surface 100A of the substrate 100 into the substrate 100. The inner separation structure 120 may extend from the first surface 100A of the substrate 100 toward the second surface 100B of the substrate 100. For example, the inner separation structure 120 may be a frontside deep trench isolation (FDTI) structure formed by filling an insulating material in a shallow trench formed by patterning the substrate 100 including the first surface 100A. For example, the inner separation structure 120 may include or consist of at least one of silicon oxide, silicon nitride, silicon oxynitride or their combination.

Referring to FIGS. 4 and 7, the inner separation structure 120 for separating the color unit region CA into the first to fourth sub regions SA1 to SA4 may be arranged in the substrate 100. The inner separation structure 120 may extend from the second surface 100B of the substrate 100 into the substrate 100. The inner separation structure 120 may extend from the second surface 100B of the substrate 100 toward the first surface 100A of the substrate 100. For example, the inner separation structure 120 may be a backside deep trench isolation (BDTI) structure formed by filling an insulating material in a shallow trench formed by patterning the substrate 100 including the second surface 100B. For example, the inner separation structure 120 may include at least one of silicon oxide, silicon nitride, silicon oxynitride or their combination.

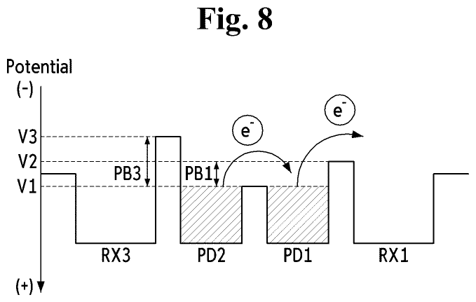

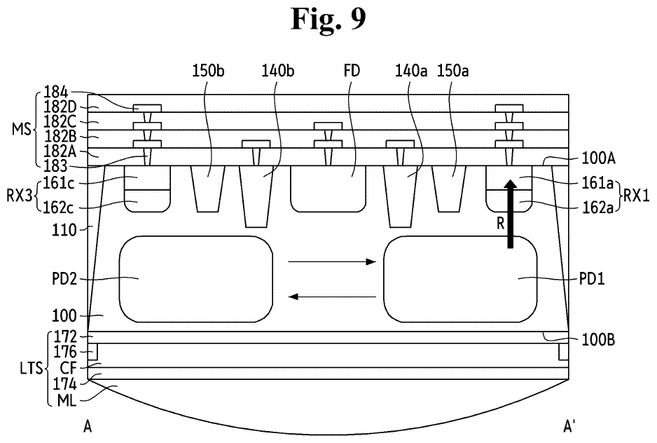

FIG. 8 is a potential view illustrating an image sensor according to some embodiments. FIG. 9 is a cross-sectional view illustrating an effect of an image sensor according to some embodiments.

Referring to FIGS. 8 and 9, during the operation of the image sensor, a first potential barrier PB1 may be provided between the first photodiode PD1 and the first source/drain region 161a by a potential level difference between the first photodiode PD1 and the first potential barrier region 162a. In addition, a third potential barrier PB3 may be provided between the second photodiode PD2 and the third source/drain region 161c by a potential level difference between the second photodiode PD2 and the third potential barrier region 162c.

As described above in FIG. 5, since a potential difference between the first photodiode PD1 and the second photodiode PD2 is not large, the electric charges between the first photodiode PD1 and the second photodiode PD2 may overflow.

In addition, a doping concentration of the first potential barrier region 162a, which forms a potential barrier between the first photodiode PD1 and the first source/drain region 161a, may be lower than a doping concentration of the third potential barrier region 162c, which forms a potential barrier between the second photodiode PD2 and the third source/drain region 161c. The first potential barrier may be lower than the third potential barrier.

In the high-illumination environment, photocharges of the first to fourth photodiodes PD1 to PD4 in the color unit region CA, which are greater than or equal to the full well capacity (FWC), may be provided. Accordingly, the electric charges overflowed in the first to fourth photodiodes PD1 to PD4 may flow to the first source/drain region 161a through the first potential barrier region 162a having a low potential barrier along the discharge path R. Because the overflow of electric charges is possible between the plurality of photodiodes PD1, PD2, PD3 and PD4 in the color unit region CA, one photodiode (the first photodiode PD1 in FIG. 5) may function as the discharge path for the entire color unit region CA. The discharge path may be a joint discharge path (e.g., a combined discharge path) that provides discharge of electric charges for two or more photodiodes. In addition, the charges overflowed from the first to fourth photodiodes PD1 to PD4 may be discharged along the discharge path R through the first potential barrier region 162a with a lower potential barrier to the first source/drain region 161a. By discharging the overflowed charges through the first source/drain region 161a rather than directly into the floating diffusion (FD) region, sunspot defects caused by fluctuations in the reset level can be prevented. As a result, since the discharge path is not required for each of the plurality of sub-regions SA1, SA2, SA3 and SA4, an image sensor in which process efficiency is increased and a sunspot defect is resolved may be provided. Although only one joint discharge path for the entire color unit region CA has been described in the present disclosure, this is exemplary, and the embodiments of the present disclosure are not limited thereto. There may be two or more joint discharge paths for the color unit region CA.

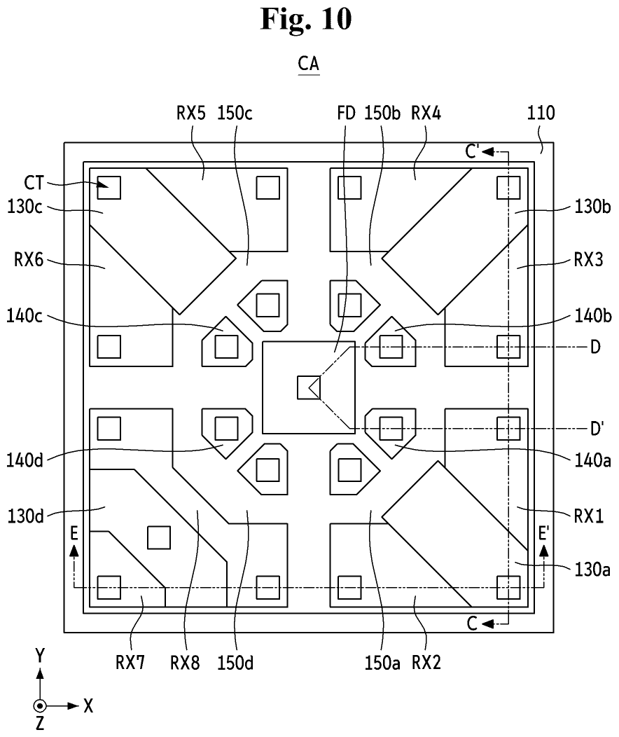

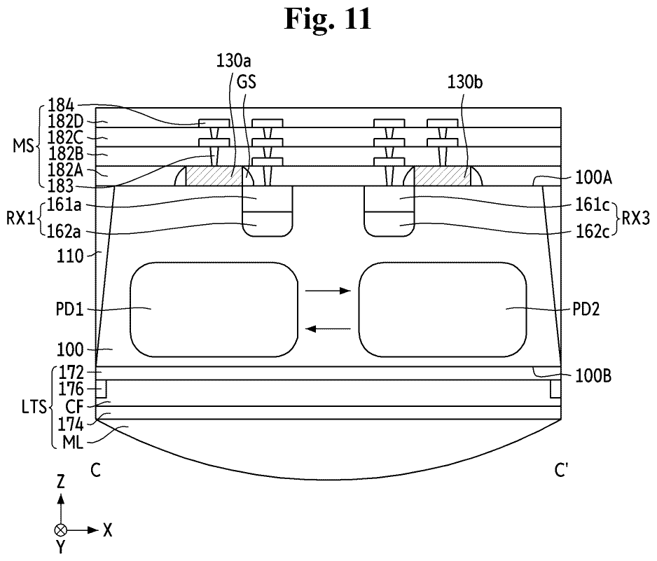

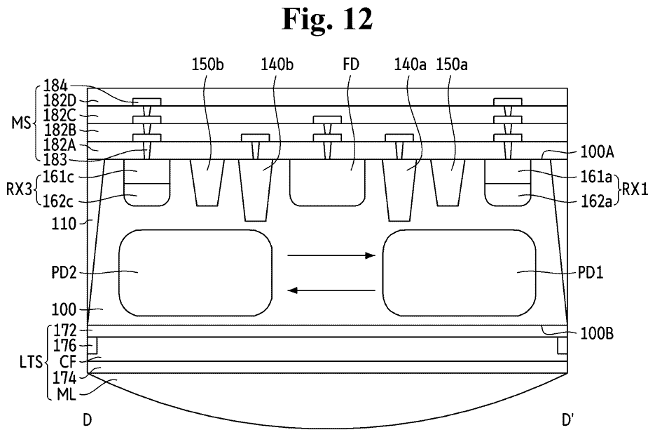

FIG. 10 is a schematic plan view illustrating some components of an image sensor according to some embodiments. FIG. 11 is a cross-sectional view taken along line C-C′ of FIG. 10. FIG. 12 is a cross-sectional view taken along line D-D′ of FIG. 10. Since the contents described in FIG. 4 are applied to the components of FIG. 10, which have the same reference numerals as those in FIG. 4, the description of the corresponding components of FIG. 10 will be omitted for convenience, and the following description will be based on differences from FIG. 4.

Referring to FIGS. 10 and 11, in some embodiments, an image sensor 10 that does not include an inner separation structure (120 of FIG. 4) in a color unit region CA may be provided. Therefore, an overflow of electric charges may occur between the first photodiode PD1 and the second photodiode PD2.

Referring to FIGS. 10 and 12, a doping concentration of the first potential barrier region 162a may be different from a doping concentration of the third potential barrier region 162c. For example, the doping concentration of the first potential barrier region 162a may be lower than the doping concentration of the third potential barrier region 162c. As the first potential barrier region 162a having a low doping concentration is provided, a potential barrier between the first photodiode PD1 and the first source/drain region 161a may be lowered.

Also, an overflow of electric charges may occur between the first to fourth photodiodes PD1 to PD4. Therefore, the electric charges exceeding the full well capacity (FWC) of the first to fourth photodiodes PD1 to PD4 may flow to the first source/drain region 161a through the first potential barrier region 162a having a low potential barrier. The first source/drain region 161a may be electrically connected to the pixel voltage VPIX through the wiring layer 184. The electric charges accumulated in the first source/drain region 161a may be discharged by the pixel voltage VPIX. Therefore, the first source/drain region 161a may function as a discharge path in the color unit region CA.

Since the overflow of electric charges is possible between the plurality of photodiodes PD1, PD2, PD3 and PD4 in the color unit region CA, one photodiode (the first photodiode PD1 in FIG. 5) may function as the joint discharge path for the entire color unit region CA. As a result, since the discharge path is not required for each of the plurality of sub-regions SA1, SA2, SA3 and SA4, an image sensor in which process efficiency is increased and a sunspot defect is resolved may be provided. Although only one joint discharge path for the entire color unit region CA has been described in the present disclosure, this is exemplary, and the embodiments of the present disclosure are not limited thereto. There may be two or more joint discharge paths for the color unit region CA.

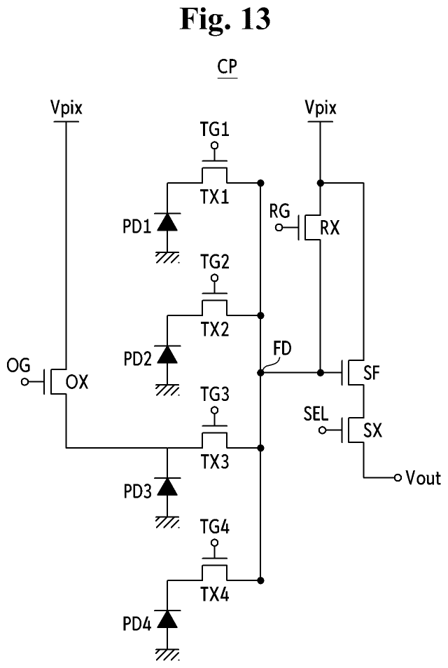

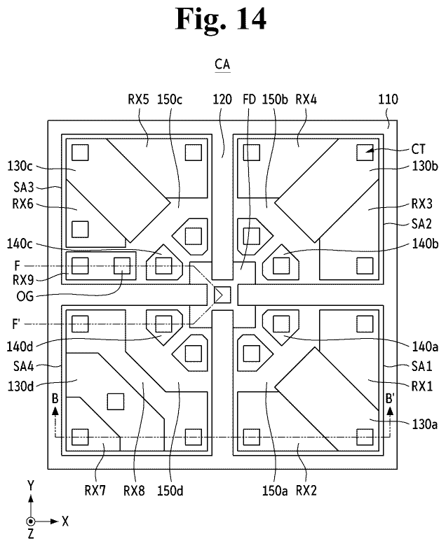

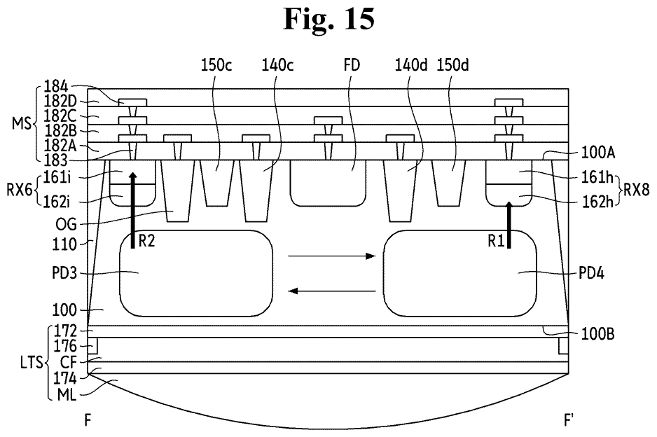

FIG. 13 is an exemplary circuit view illustrating a pixel unit included in an image sensor according to embodiments of the present disclosure. FIG. 14 is a schematic plan view illustrating some components of an image sensor according to some embodiments. FIG. 15 is a cross-sectional view illustrating effects of an image sensor according to some embodiments.

Referring to FIGS. 13 to 15, a color unit pixel CP according to some embodiments of the present disclosure may further include an overflow transistor OX as compared with FIG. 2. The overflow transistor OX may be turned on and off by an overflow gate signal OG. A drain electrode of the overflow transistor OX is connected to the pixel voltage VPIX.

When the overflow transistor OX is turned on, electric charges accumulated in the third photodiode PD3 may be discharged along a second discharge path R2 to prevent the first to fourth photodiodes PD1 to PD4 from being saturated.

Referring to FIGS. 14 and 15, the image sensor 10 according to some embodiments may further include an overflow transistor OX in the third sub-region SA3 as compared with FIG. 4.

An overflow may occur between the third and fourth photodiodes PD3 and PD4 adjacent to each other. Accordingly, an electric charge amount exceeding a full well capacity (FWC) in either the third photodiode PD3 or the fourth photodiode PD4 may flow to the first to fourth photodiodes PD1 to PD4. However, in the high-illumination environment, the electric charges in the third photodiode PD3 or the fourth photodiode PD4, which exceed the full well capacity (FWC) of the first to fourth photodiode PD1 to PD4, may flow to the floating diffusion region FD. In this case, a reset level of the floating diffusion region FD may be reduced, whereby a sunspot defect may occur.

According to some embodiments of the present disclosure, a doping concentration of the eighth potential barrier region 162h may be lower than a doping concentration of the ninth potential barrier region 162i. As the eighth potential barrier region 162h having a low doping concentration is provided, a potential barrier between the fourth photodiode PD4 and the eighth source/drain region 161h may be lowered. Therefore, the electric charges exceeding the full well capacity (FWC) in the fourth photodiode PD4 may overflow to the eighth source/drain region 161h. The eighth source/drain region 161h may be electrically connected to the pixel voltage VPIX through the wiring layer 184. The electric charges accumulated in the eighth source/drain region 161h may be discharged by the pixel voltage VPIX. That is, the eighth source/drain region 161h may function as a discharge path in the color unit region CA.

Also, an overflow of electric charges may occur between the first to fourth photodiodes PD1 to PD4. Therefore, the electric charges exceeding the full well capacity (FWC) of the first to fourth photodiodes PD1 to PD4 may flow to the eighth source/drain region 161h. That is, since the overflow of electric charges is possible between the plurality of photodiodes PD1, PD2, PD3 and PD4 in the color unit region CA, one photodiode (the fourth photodiode PD4 in FIG. 14) may function as the discharge path for the entire color unit region CA. As a result, since the discharge path is not required for each of the plurality of sub-regions SA1, SA2, SA3 and SA4, process efficiency may be increased. Also, since the overflow transistor OX is additionally formed in the color unit region CA, electric charges exceeding the FWC of the photodiodes PD1, PD2, PD3 and PD4 may be efficiently discharged. As a result, an image sensor in which a sunspot defect is resolved may be provided.

Although the embodiments of the present disclosure have been described with reference to the accompanying drawings, it will be apparent to those skilled in the art that the present disclosure can be manufactured in various forms without being limited to the above-described embodiments and can be embodied in other specific forms without departing from the technical spirits and essential characteristics. Thus, the above embodiments are to be considered in all respects as illustrative and not restrictive.

What is claimed is:

1. An image sensor comprising:
a substrate; and
an outer separation structure separating the substrate into a plurality of color unit regions,
wherein:
each of the color unit regions includes a plurality of sub-regions and a floating diffusion region, and
for each color unit region, the plurality of sub-regions include a first sub-region and a second sub-region, which share the floating diffusion region, and
each of the sub-regions includes:
a first doped region arranged adjacent to a first surface of the substrate and doped with impurities having a first conductivity type,
a second doped region spaced apart from the first surface and doped with impurities having a second conductivity type different from the first conductivity type, the first doped region being arranged between the first surface and the second doped region, and
a third doped region spaced apart from the first surface and doped with impurities having the first conductivity type, and
a doping concentration of the second doped region of the first sub-region is different from a doping concentration of the second doped region of the second sub-region.

2. The image sensor of claim 1, wherein the doping concentration of the second doped region of the first sub-region is lower than the doping concentration of the second doped region of the second sub-region.

3. The image sensor of claim 1, wherein each first doped region is electrically connected to a pixel voltage source.

4. The image sensor of claim 3, wherein for each color unit region, the second doped region of the first sub-region is doped to have a first impurity concentration,
the second doped region of the second sub-region is doped to have a second impurity concentration higher than the first impurity concentration, and
a potential barrier between the first doped region of the first sub-region and the third doped region of the first sub-region is smaller than a potential barrier between the first doped region of the second sub-region and the third doped region of the second sub-region.

5. The image sensor of claim 1, wherein for each color unit region, the plurality of sub-regions further includes a third sub-region and a fourth sub-region,
the image sensor further comprising an inner separation structure arranged between adjacent sub-regions among the first to fourth sub-regions, the inner separation structure passing through at least a portion of the substrate.

6. The image sensor of claim 5, wherein the inner separation structure includes frontside deep trench isolation (FTDI) or backside deep trench isolation (BDTI).

7. The image sensor of claim 5, wherein for each color unit region, a doping concentration of at least one second doped region of the first to fourth sub-regions is a first level,
a doping concentration of at least one second doped region, which is not doped with the first level, among the first to fourth sub-regions is a second level, and
the first level is a lower than the second level.

8. The image sensor of claim 5, wherein for each color unit region, the third sub-region includes an overflow transistor that provides electric charges in the third doped region of the third sub-region to the first doped region of the third sub-region.

9. The image sensor of claim 5, wherein each of the first to the fourth sub-regions includes a transmission transistor that provides electric charges in the third doped region to the floating diffusion region.

10. The image sensor of claim 1, wherein for each sub-region, the third doped region includes a photodiode that generates electric charges by reacting with light.

11. The image sensor of claim 10, wherein for each sub-region, the first doped region is a source/drain region, the second doped region is a potential barrier region, and the third doped region is a photodiode.

12. The image sensor of claim 1, further comprising:
a wiring layer formed on the first surface of the substrate, including wirings electrically connected to the substrate;
a color filter formed on a second surface opposite to the first surface of the substrate; and
a microlens formed on the color filter,
wherein for each color unit region, the sub-regions share the color filter and the microlens.

13. An image sensor comprising:
a substrate;
an outer separation structure separating the substrate into a plurality of color unit regions; and
an inner separation structure separating each of the color unit regions into first to fourth sub-regions and passing through at least a portion of the substrate,
wherein each of the color unit regions includes a floating diffusion region,
wherein for each color unit region, the first to fourth sub-regions share a floating diffusion region and each include:
a first doped region arranged adjacent to a first surface of the substrate and doped with impurities having a first conductivity type,
a second doped region spaced apart from the first surface and doped with impurities having a second conductivity type different from the first conductivity type, the first doped region being arranged between the first surface and the second doped region, and
a third doped region spaced apart from the first surface and doped with impurities having the first conductivity type, and
wherein a doping concentration of the second doped region of the first sub-region is less than a doping concentration of the second doped region of the second sub-region.

14. The image sensor of claim 13, wherein for each color unit region, the first doped region of the first sub-region is electrically connected to a pixel voltage source.

15. The image sensor of claim 13, wherein for each color unit region, a potential barrier between the first doped region and the third doped region of the first sub-region is smaller than a potential barrier between the first doped region and the third doped region of the second sub-region.

16. The image sensor of claim 13, wherein each third doped region includes a photodiode that generates electric charges by reacting with light.

17. The image sensor of claim 13, wherein the inner separation structure includes FDTI or BDTI.

18. The image sensor of claim 13, wherein for each color unit region:
each of the first to the fourth sub-regions includes a transmission transistor that provides electric charges in the third doped region to the floating diffusion region, and
the third sub-region includes an overflow transistor that provides the electric charges in the third doped region of the third sub-region to the first doped region of the third sub-region.

19. The image sensor of claim 13, further comprising:
a wiring layer formed on the first surface of the substrate, including wirings electrically connected to the substrate;
a color filter formed on a second surface opposite to the first surface of the substrate; and
a microlens formed on the color filter,
wherein for each color unit region, the first to fourth sub-regions share the color filter and the microlens.

20. An image sensor comprising:
a substrate;
an outer separation structure separating the substrate into a plurality of color unit regions;
an inner separation structure separating each color unit region of the color unit regions into first to fourth sub-regions and passing through at least a portion of the substrate;
a wiring layer formed on a first surface of the substrate, including wirings electrically connected to the substrate;
a color filter formed on a second surface opposite to the first surface of the substrate; and
a microlens formed on the color filter,
wherein for each color unit region:
the color unit region includes a floating diffusion region,
the first to fourth sub-regions share the floating diffusion region and each includes:
a first doped region electrically connected to a pixel power source through the wiring and doped with impurities having a first conductivity type,
a second doped region spaced apart from the first surface and doped with impurities having a second conductivity type different from the first conductivity type, the first doped region being arranged between the first surface and the second doped region,
a third doped region doped with impurities having the first conductivity type, the third doped region generating electric charges by reacting with light, and
a transmission transistor providing the electric charges in the third doped region to the floating diffusion region, and
a doping concentration of the second doped region of the first sub-region is less than a doping concentration of the second doped region of the second sub-region.
